(19) United States
(12) Patent Application Publication
(10) Pub. No.: US 2014/0110714 A1
(43) Pub. Date: Apr. 24, 2014

(54) HIGH MOBILITY COMPOUND SEMICONDUCTOR MATERIAL USING MULTIPLE ANIONS

(71) Applicant: Applied Materials, Inc., Santa Clara, CA (US)

(72) Inventor: Yan YE, Saratoga, CA (US)

(73) Assignee: APPLIED MATERIALS, INC., Santa Clara, CA (US)

(21) Appl. No.: 14/039,046

(22) Filed: Sep. 27, 2013

Related U.S. Application Data
(60) Provisional application No. 61/716,714, filed on Oct. 22, 2012.

(51) Int. Cl. H01L 29/786; H01L 29/66

(52) U.S. Cl. CPC H01L 29/786; H01L 29/6675
USPC 257/57; 423/409; 423/592.1; 423/622; 423/624; 423/618; 423/594.18; 423/351; 423/473; 438/151

(57) ABSTRACT

The present invention generally relates to an amorphous semiconductor material and TFTs containing the material. The semiconductor material contains a single cation, such as zinc, and multiple anions. For the multiple anions, only one of the anions can be oxygen or nitrogen. The anions compete with each other to twist the resulting structure. For example, if one of the anions bonded with the cation would result in a cubic structure, and another of the anions bonded with the cation would result in a hexagonal structure, the competing anions would twist the resulting structure so that the structure remains amorphous rather than crystalline. Further, because a single cation is utilized, there is no grain boundary and thus, the material has a high mobility.

### CROSS-REFERENCE TO RELATED APPLICATIONS

This application claims benefit of U.S. Provisional Patent Application Ser. No. 61/716,714 (APPM/17163L), filed Oct. 22, 2012, which is herein incorporated by reference.

### BACKGROUND OF THE INVENTION

1. Field of the Invention

Embodiments of the present invention generally relate to a semiconductor material that contains a single cation and multiple anions. The semiconductor material can be used in a thin film transistor (TFT).

2. Description of the Related Art

Current interest in TFT arrays is particularly high because these devices may be used in liquid crystal active matrix displays (LCDs) of the kind often employed for computer and television flat panels. The LCDs may also contain light emitting diodes (LEDs), such as organic light emitting diodes (OLEDs) for back lighting. The LEDs and OLEDs require TFTs for addressing the activity of the displays.

The current driven through the TFTs (i.e., the on-current) is limited by the channel material (often referred to as the active material, semiconductor material or semiconductor active material) as well as the channel width and length. Additionally, the turn-on voltage is determined by the accumulation of the carrier in the channel area of the semiconductor layer which could change as the shift of the fixed charge in the semiconductor material or the charge trapping in interfaces and the threshold voltage shifts after bias temperature stress or current temperature stress.

Silicon, as the semiconductor material, has its limitations. Amorphous silicon has a low mobility. Polycrystalline silicon, while having a higher mobility than amorphous silicon, but is expensive to produce and necessitates an annealing process.

Therefore, there is a need in the art for a semiconductor material that has high mobility, yet can be produced at a low cost.

### SUMMARY OF THE INVENTION

The present invention generally relates to an amorphous semiconductor material and TFTs containing the material. The semiconductor material contains a single cation, such as zinc, and multiple anions. For the multiple anions, only one of the anions can be oxygen or nitrogen. The anions compete with each other to twist the resulting structure. For example, if one of the anions bonded with the cation would result in a cubic structure, and another of the anions bonded with the cation would result in a hexagonal structure, the competing anions would interrupt the preferential growth of either crystalline structure so that grain boundary formation is suppressed, and the structure is formed towards amorphous rather than crystalline. Further, because a single cation is utilized, there is no barrier resulting from multi-cations for electron transport and thus, the material has a high electron mobility.

In one embodiment, an amorphous semiconductor compound, comprising a single cation and multiple anions, wherein at most one anion comprises nitrogen or oxygen is disclosed.

In another embodiment, a thin film transistor comprising a gate electrode; a gate dielectric layer disposed over the gate electrode; an amorphous semiconductor layer disposed over the gate dielectric layer, the amorphous semiconductor layer comprising a single cation and multiple anions, wherein at most one cation comprises nitrogen or oxygen; and source and drain electrodes disposed over the amorphous semiconductor layer is disclosed.

In another embodiment, a method of making a thin film transistor, comprising depositing an amorphous semiconductor layer over a gate dielectric layer, the amorphous semiconductor layer comprising a single cation and multiple anions, wherein at most one cation comprises nitrogen or oxygen is disclosed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional schematic view of a PVD chamber according to one embodiment of the invention.

FIGS. 2A-2C are schematic cross-sectional views of a TFT 200 at various stages of production.

FIG. 3 is a schematic isometric illustration of a crystalline, semiconductor material.

FIG. 4 is a schematic isometric illustration of an amorphous, multi-cation semiconductor material.

FIG. 5 is a schematic isometric illustration of an amorphous, single cation, multi-anion semiconductor material.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally relates to a semiconductor material in which grain boundary is suppressed and TFTs containing the material. The semiconductor material contains a single cation, such as zinc, and multiple anions. The anions compete with each other to twist the resulting structure. For example, if one of the anions bonded with the cation would result in a cubic structure, and another of the anions bonded with the cation would result in a hexagonal structure, the competing anions would interrupt the preferential growth of either crystalline structure so that the formed structure is toward amorphous rather than crystalline, and grain boundary formation is suppressed. Further, because a single cation is utilized, there is no barrier resulting from different cations adjacent with each other to hurdle the electron transport and thus, the material has a high electron mobility.

The invention is illustratively described and may be used in a PVD chamber for processing large area substrates, such as a 4300 PVD chamber, available from AKT®, a subsidiary of Applied Materials, Inc., Santa Clara, Calif. However, it should be understood that the sputtering target may have utility in other system configurations, including those systems configured to process large area round substrates and those systems produced by other manufacturers.

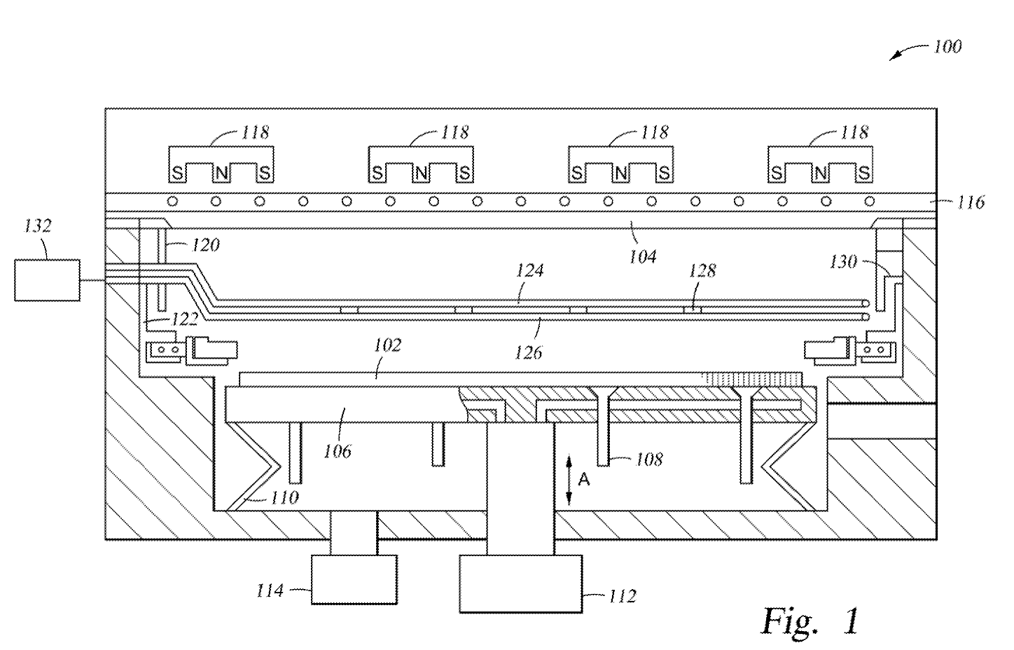

FIG. 1 is a cross-sectional schematic view of a PVD chamber 100 according to one embodiment of the invention. The chamber 100 may be evacuated by a vacuum pump 114. Within the chamber 100, a substrate 102 may be disposed opposite a target 104. The substrate may be disposed on a susceptor 106 within the chamber 100. The susceptor 106 may be elevated and lowered as shown by arrows “A” by an actuator 112. The susceptor 106 may be elevated to raise the substrate 102 to a processing position and lowered so that the substrate 102 may be removed from the chamber 100. Lift pins 108 elevate the substrate 102 above the susceptor 106 when the susceptor 106 is in the lowered position. Grounding straps 110 may ground the susceptor 106 during processing. The susceptor 106 may be raised during processing to aid in uniform deposition.

The target 104 may comprise one or more targets 104. The target 104 may be bonded to a backing plate 116 by a bonding layer. To control the temperature of the target 104, cooling channels may be present in the backing plate 116. One or more magnetrons 118 may be disposed behind the backing plate 116. The magnetrons 118 may scan across the backing plate 116 in a linear movement or in a two dimensional path. The walls of the chamber may be shielded from deposition by a dark space shield 120 and a chamber shield 122.

To help provide uniform sputtering deposition across a substrate 102, an anode 124 may be placed between the target 104 and the substrate 102. In one embodiment, the anode 124 may be bead blasted stainless steel coated with arc sprayed aluminum. In one embodiment, one end of the anode 124 may be mounted to the chamber wall by a bracket 130. The anode 124 provides a charge in opposition to the target 104 so that charged ions will be attracted thereto rather than to the chamber walls which are typically at ground potential. By providing the anode 124 between the target 104 and the substrate 102, the plasma may be more uniform, which may aid in the deposition.

For reactive sputtering, it may be beneficial to provide a reactive gas into the chamber 100. One or more gas introduction tubes 126 may also span the distance across the chamber 100 between the target 104 and the substrate 102. The gas introduction tubes 126 may introduce sputtering gases such as inert gases including argon as well as reactive gases such as oxygen, nitrogen, etc. The gases may be provided to the gas introduction tubes 126 from a gas panel 132 that may introduce one or more gases such as argon, oxygen, and nitrogen. The gas introduction tubes 126 may be disposed between the substrate 102 and the target 104 at a location below the one or more anodes 124. The anodes 124 may shield the gas introduction tubes 126 from deposition during processing. Shielding the gas introduction tubes 126 with the anodes 124 may reduce the amount of deposition that may cover or clog the gas outlets. The gas introduction tubes 126 may be coupled with the anodes 124 by one or more couplers 128.

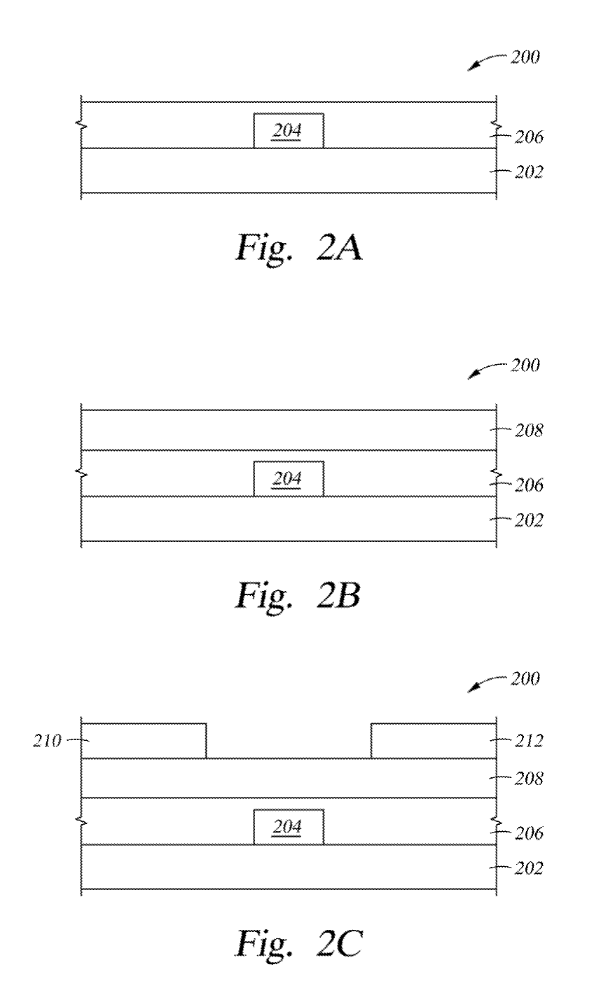

FIGS. 2A-2C are schematic cross-sectional views of a TFT 200 at various stages of production. As shown in FIG. 2A, a gate electrode 204 is formed over a substrate 202. Suitable materials that may be utilized for the substrate 202 include, but not limited to, silicon, germanium, silicon-germanium, soda lime glass, glass, semiconductor, plastic, steel or stainless steel substrates. Suitable materials that may be utilized for the gate electrode 204 include, but are not limited to, chromium, copper, aluminum, tantalum, titanium, molybdenum, and combinations thereof, or transparent conductive oxides (TCO) such as indium tin oxide (ITO) or fluorine doped zinc oxide (ZnO:F) which are commonly used as transparent electrodes. The gate electrode 204 may be deposited by suitable deposition techniques such as PVD, MOCVD, a spin-on process and printing processes. The gate electrode 204 may be patterned using an etching process.

Over the gate electrode 204, a gate dielectric layer 206 may be deposited. Suitable materials that may be used for the gate dielectric layer 206 include silicon dioxide, silicon oxynitride, silicon nitride, aluminum oxide or combinations thereof. The gate dielectric layer 206 may be deposited by suitable deposition techniques including plasma enhanced chemical vapor deposition (PECVD).

A semiconductor layer 208 is then formed over the gate dielectric layer 206 as shown in FIG. 2B. In practice, the semiconductor layer 208 is oftentimes referred to as the channel layer, the active layer or the semiconductor active layer. As shown in FIG. 2C, over the semiconductor layer 208, the source electrode 210 and the drain electrode 212 are formed. The exposed portion of the semiconductor layer 208 between the source and drain electrodes 210, 212 is referred to as the active channel 214. Suitable materials for the source and drain electrodes 210, 212 include chromium, copper, aluminum, tantalum, titanium, molybdenum, and combinations thereof, or TCOs mentioned above. The source and drain electrodes 210, 212 may be formed by suitable deposition techniques, such as PVD followed by patterning through etching.

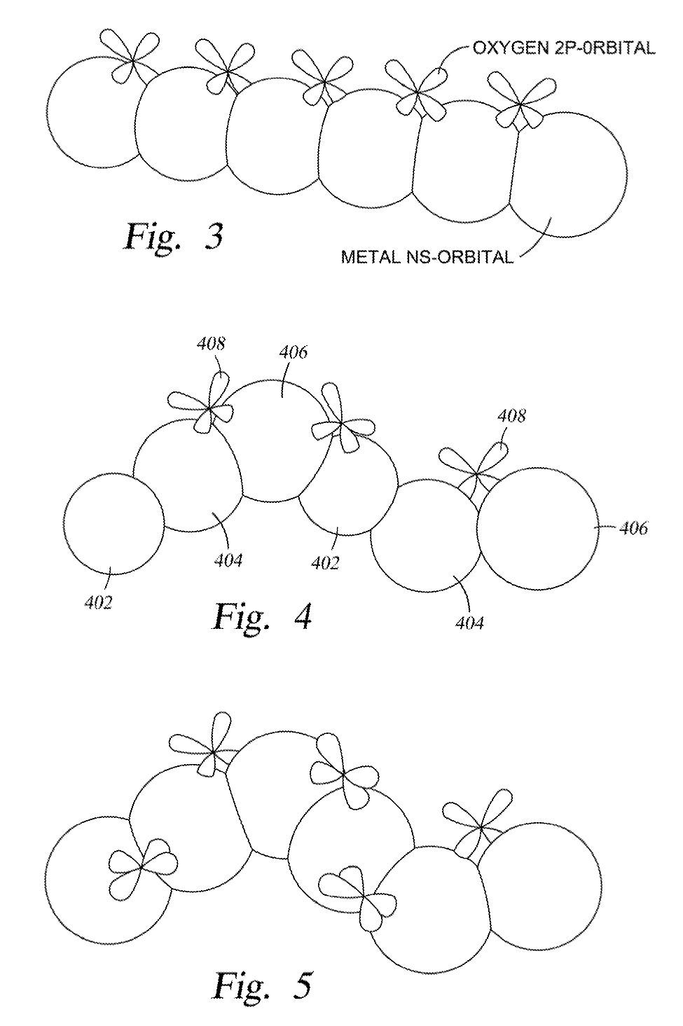

FIG. 3 is a schematic isometric illustration of a crystalline semiconductor material either in a single crystalline film or inside a grain in a polycrystalline film. An example of the crystalline semiconductor material is zinc oxide where oxygen is the anion and zinc is the cation. The crystalline structure has a hexagonal structure. As shown in FIG. 3, the overlap of the Zn 4s-orbitals configurate the conduction bands of the materials. The 2p-orbitals, because oxygen is the single anion, align to create a crystalline structure. Because a single cation is used such as zinc, all line up perfectly and are all the same size. Thus, there is no electron transport barrier created by different cations adjacent and there is a high electron mobility.

FIG. 4 is a schematic isometric illustration of multi-cation semiconductor material. As shown in FIG. 4, the material comprises three different cations, such as indium, gallium and zinc. The cations all have different ns-orbitals as shown by the rings 402, 404, 406. Because the different cations demand different crystal structures, the structure twists and is thus amorphous.

Even though a single anion, such as oxygen, is present as represented by the 2p-orbital, the cations dominate the structure and thus control the orientation of the structure. Because of the different ns-orbitals for the three cations, the grain boundary formation is suppressed. However, due to overlap of the different ns-orbitals of the different cations, a barrier acting like a grain boundaries exist and thus, mobility is not ideal.

It is observed that the mobility of multi-component metal oxides (i.e., multi-cation metal oxides such as an IGZO) is much lower than their binary compound (i.e., zinc oxide) ingredient. The different relationships of mobility and carrier concentration for a multi-component metal oxide and a ZnON strongly suggested that the transport of electron carriers in multi-component oxides is interrupted by the overlapping of different S-orbitals from different cations. To address the issue to increase the mobility of a compound semiconductor, it is proposed to form a high mobility semiconductor through at least two anions and single cation system. The cations may be N, O, S, P, C, F, I, As, Se, and so on.

FIG. 5 is a schematic isometric illustration of an amorphous, single cation, multi-anion semiconductor material that may be used in the TFT shown in FIGS. 2A-2C. As shown in FIG. 5, all of the ns-orbitals are the same size, just as in FIG. 3, because a single cation is present, yet the structure is not crystalline. Suitable cations that may be used include transition metals, In, Sn, Ga, Cd, and Zn. Multiple anions are present with the single cation. The anions compete with each other and thus, twist the structure. For example, if the cation is zinc and the anions are oxygen and nitrogen, the structure will twist. Zinc nitride is a cubic structure while zinc oxide is a hexagonal structure. The nitrogen and oxygen compete with one another and thus, neither a cubic nor a hexagonal crystalline structure forms easily. Rather, an amorphous structure forms more favorably. Additionally, because a single cation is used, there is no grain-boundary-like barrier resulting from multi-cations.

It is to be understood that the anions are not limited to oxygen and nitrogen. Other suitable anions that may be used include iodine, fluorine, sulfur, chlorine, and bromine. It is contemplated that high doses of hydrogen or argon may be used as well. Generally, any two anions may be used so long as the anions interrupt the crystalline formation that would naturally occur when using a single cation. In one embodiment, two anions are utilized, however, it is contemplated that more anions may be present.

By utilizing a single cation and multiple anions, an amorphous structure can be formed that has no grain boundary and thus a high mobility.

While the foregoing is directed to embodiments of the present invention, other and further embodiments of the invention may be devised without departing from the basic scope thereof, and the scope thereof is determined by the claims that follow.

1. An amorphous semiconductor compound, comprising a single cation and multiple anions, wherein at most one anion comprises nitrogen or oxygen.

2. The compound of claim 1, wherein the cation is a transition metal.

3. The compound of claim 1, wherein the cation is selected from the group consisting of In, Sn, Ga, Cd, and Zn.

4. The compound of claim 1, wherein the multiple anions comprise at least one of iodine, fluorine, sulfur, chlorine, and bromine.

5. The compound of claim 1, wherein the multiple anions comprise two anions.

6. The compound of claim 1, wherein the multiple anions comprise oxygen and another anion.

7. The compound of claim 6, wherein cation comprises zinc.

8. A thin film transistor, comprising:
a gate electrode;
a gate dielectric layer disposed over the gate electrode;
an amorphous semiconductor layer disposed over the gate dielectric layer, the amorphous semiconductor layer comprising a single cation and multiple anions, wherein at most one cation comprises nitrogen or oxygen; and
source and drain electrodes disposed over the amorphous semiconductor layer.

9. The thin film transistor of claim 8, wherein the cation is a transition metal.

10. The thin film transistor of claim 8, wherein the cation is selected from the group consisting of In, Sn, Ga, Cd, and Zn.

11. The thin film transistor of claim 8, wherein the multiple anions comprise at least one of iodine, fluorine, sulfur, chlorine, and bromine.

12. The thin film transistor of claim 8, wherein the multiple anions comprise two anions.

13. The thin film transistor of claim 8, wherein the multiple anions comprise oxygen and another anion.

14. The thin film transistor of claim 13, wherein cation comprises zinc.

15. A method of making a thin film transistor, comprising depositing an amorphous semiconductor layer over a gate dielectric layer, the amorphous semiconductor layer comprising a single cation and multiple anions, wherein at most one cation comprises nitrogen or oxygen.

16. The method of claim 15, wherein the cation is a transition metal.

17. The method of claim 15, wherein the cation is selected from the group consisting of In, Sn, Ga, Cd, and Zn.

18. The method of claim 15, wherein the multiple anions comprise at least one of iodine, fluorine, sulfur, chlorine, and bromine.

19. The method of claim 15, wherein the multiple anions comprise two anions.

20. The method of claim 15, wherein the multiple anions comprise oxygen and another anion.

21. The method of claim 20, wherein cation comprises zinc.
